(19) United States
(12) Patent Application Publication
(10) Pub. No.: US 2026/0135348 A1
(43) Pub. Date: May 14, 2026

(54) TUNABLE LASER ARCHITECTURE

(71) Applicant: Alpine Optoelectronics Inc., Fremont, CA (US)

(72) Inventors: Guoliang Li, Albuquerque, NM (US); Zhoufeng Ying, Newark, CA (US); Chenghao Feng, Milpitas, CA (US)

(21) Appl. No.: 18/947,321

(22) Filed: Nov. 14, 2024

(51) Int. Cl. H01S 5/14; H01S 5/00; H01S 5/028; H01S 5/10

(52) U.S. Cl. CPC H01S 5/14; H01S 5/0064; H01S 5/0287; H01S 5/1007

(57) ABSTRACT

A tunable laser architecture is provided having: a photonics chip having: an asymmetrical optical splitter, a first branching waveguide in optical communication with the asymmetrical optical splitter, wherein the first branching waveguide is configured to be in optical communication with a laser output; a second branching waveguide in optical communication with the asymmetrical optical splitter; a first Vernier ring in optical communication with the first branching waveguide; a second Vernier ring in optical communication with the second branching waveguide; and a monitor pathway waveguide in optical communication with the first and second Vernier rings, wherein the monitor pathway waveguide is configured to be in optical communication with a monitor photodetector. The tunable laser architecture experiences low optical losses and low non-linearity effect, as a result of only passing through each Vernier ring once per round trip and having its laser output via a single-ring thru-port without going through ring losses.

### BACKGROUND OF INVENTION

### 1. Field of the Invention

The invention relates generally to tunable laser architectures and more specifically to tunable laser architectures having an asymmetric Vernier ring.

### 2. Description of the Related Art

Silicon photonics-based devices are popular for many applications, including optical communication, computing, LiDAR, bio/medical sensing, display, and data storage. Certain applications require silicon (“Si”) photonics circuits to use wavelength tunable laser sources. It would be ideal to integrate such tunable laser sources with Si photonics chips, which would offer significant benefits when compared to alternative structures, while having a lower cost, lower power consumption, and a smaller size.

Since Si is a semiconductor material with indirect bandgap, it does not lase. A Si photonics integrated tunable laser typically uses a III-V semiconductor gain chip to couple with a Si photonics chip. The III-V semiconductor gain chip provides optical gain, while the Si photonics chip contains wavelength tuning and monitoring circuits, integrated with other functioning circuits for various applications. The wavelength tuning on the Si photonics chip may be implemented using Vernier rings, which may be utilized for their wide tuning ranges and low power consumption. The waveguides for Vernier rings could be either Si waveguides (for low tuning power) or silicon nitride (“SiN”) waveguides (for high laser power and narrow linewidth), depending on application needs. It should be understood that Si photonics chips can contain both Si waveguides and SiN waveguides. Other waveguide materials may also be utilized, depending on application requirements.

FIG. 1 illustrates an example of a tunable laser architecture 100 having Vernier rings 107, 108, according to an aspect. FIG. 2 illustrates a typical transmission spectrum for Vernier rings of a laser architecture using the Vernier rings for wavelength control, according to an aspect. As seen in FIG. 1, a tunable laser architecture 100 is provided, wherein a pair of Vernier rings 107, 108 are configured to provide tuning capabilities to a corresponding silicon photonics chip (“Si photonics chip”, “photonics chip”) 105 of the tunable laser architecture 100. This tunable laser architecture 100 may comprise a semiconductor gain chip (“III-V semiconductor gain chip”, “III-V gain chip”, “gain chip”) 101 having a high reflectivity coating 102 on a first end and an anti-reflection coating 103 on a second end, wherein the semiconductor gain chip 101 is in optical communication with a silicon photonics chip 105 via a corresponding laser input 105a. The corresponding side of the silicon photonics chip 105 having the laser input 105a may also have an anti-reflection coating 103. A lens 104 may be disposed between the silicon photonics chip 105 and the semiconductor gain chip. The lens 104 may be an optional element of the disclosed tunable laser architecture 100, wherein the disclosed lens 104 is configured to reduce the optical coupling loss between the photonics chip 105 and the semiconductor gain chip 101 when the optical mode sizes of the photonics chip 105 and the semiconductor gain chip 101 are small or very different. In alternative embodiments, spot-size converters (not shown) may be implemented at the corresponding couple edges of each chip 101, 105, (e.g., the edges of the photonics chip 105 and the semiconductor gain chip 101 that light travels between during tunable laser architecture operation), wherein spot-size converters are configured to enlarge and match the mode sizes on the two chips 101, 105. When utilizing the spot-size converters as disclosed hereinabove, the lens 104 may be omitted, in order to save cost and package size.

As can be seen in FIG. 1, the silicon photonics chip 105 comprises a phase heater 106, a first Vernier ring 107 in optical communication with the phase heater 106, a second ring 108 in optical communication with the first Vernier ring 107, and a partial mirror 109 in optical communication with the second Vernier ring 108, wherein the partial mirror 109 is in optical communication with the laser output 105b of the silicon photonics chip 105. It should be understood that the term “optical communication” may be utilized to indicate that corresponding elements are optically coupled, optically connected or otherwise optically associated with each other, such that when two elements are in optical communication with each other, an optical signal traveling through one of the elements may also travel though the other (sequentially, simultaneously or otherwise). In an embodiment, elements having an “optical connection” (e.g., elements that are optically connected) should be understood as having a connected waveguide path (such as the main waveguide 413 and the optical splitter 414 of FIG. 4), whereas elements that have an “optical coupling” (e.g., elements that are optically coupled) should be understood as having a non-connected optical path (such as the first Vernier ring 417 and the first branching waveguide 415 of FIG. 4). Again, the phrase “optical communication” encompasses both “optical connection” and “optical coupling” relations, amongst other possible optical associations.

In an embodiment, the partial mirror 109 is configured to reflect a portion of a laser traveling into the silicon photonics chip 105 from the semiconductor gain chip 101 back into the semiconductor gain chip 101. As can be seen in FIG. 1, the first Vernier ring 107 and second Vernier ring 108 are in series, such that a laser will travel through both the first and second Vernier rings 107, 108 while traveling between the phase heater 106 and the partial mirror 109. One consequence of this is that the portion of a laser traveling through the silicon photonics chip 105 that is reflected by the partial mirror 109 back to the semiconductor gain chip 101 travels though both Vernier rings 107, 108 a second time, before being reflected by the high reflectivity coating 102 on the semiconductor gain chip back into the silicon photonics chip 105. The laser may experience optical losses each time it travels through a Vernier ring, and thus optical losses may be significant for this tunable laser architecture 100. As is understood, optical losses negatively influence device performance, and thus should be avoided to provide optimized optical devices.

Vernier rings of different sizes that are made of the same material have different resonant periods (“free spectral ranges,” “FSRs”). The transmission spectrum 210 of FIG. 2 illustrates the different resonant periods for the Vernier rings of a tunable laser architecture. As is understood, the laser wavelength(s) allowed to be transmitted through the laser output of the silicon photonics chip 105 is/are dictated by the aligned resonance pairs 210a of the Vernier rings. For example, in the embodiment of FIG. 2, the aligned resonance pair 210a for the two Vernier rings occurs at roughly 1550 nm, and thus the disclosed tunable laser architecture 100 is configured to emit a laser (out of the laser output 105b) having a wavelength of about 1550 nm. As is understood, tuning any Vernier ring over FSR can broadly tune the emitted laser wavelength.

While laser tuning devices that do not employ Vernier rings exist in the industry, each of these devices may have shortcomings that render them less viable than their Vernier ring based counterparts in many applications. One alternative laser tuning device may come in the form of semiconductor tunable lasers assembled with free-space optical components, including mirrors, collimator lens, gain chip, MEMS filters, Etalons, taps, and monitor PDs (“photodetectors, MPDs”), which are present in the market. The lasing wavelength is controlled and tuned by the MEMS filters. The main drawback of these laser tuning devices is their bulky size, which tends to be in the “cm scale,” rather than the “mm scale” of many Vernier ring based laser tuning devices.

Other alternative laser devices may use a distributed feedback (DFB) laser array instead of a single gain chip. Each DFB laser covers a small tuning range, while a MEMS switch selects one DFB laser to the output based on the target wavelength, wherein said DFB laser arrays may be stacked to achieve greater degrees of tuning. Limitations inherent within laser tuning devices that utilize DFB laser arrays may include having a lower optical yield, as well as many potential points of failure, which may negatively influence device longevity.

In another embodiment, a tunable laser device may utilize distributed Bragg gratings (DBRs) to achieve the necessary tuning. While DBR based laser tuning devices may have the advantages of being placed all on a singular chip, DBR based laser tuning devices may suffer from high optical loss (low efficiency) and low yield, while also being generally more expensive than its counterparts.

FIGS. 3A-3E illustrate prior art laser architectures having Vernier rings, according to an aspect. FIG. 3F illustrates a laser architecture having two Vernier rings and a ring thru-port laser output method, according to an aspect. FIG. 3G illustrates a table describing the configurations of the laser architectures of FIG. 3A-3F, according to an aspect. It should be understood that asymmetrical Vernier rings may be incorporated into the structure of a tunable laser architecture in a variety of ways. As can be seen in FIG. 3A-3F, the specifics regarding how the asymmetrical Vernier Rings are disposed in relation to other chip elements may vary, as further articulated in FIG. 3G.

For the laser architecture 300 of prior art FIG. 3A, an optical signal may be configured to travel through each Vernier ring 307, 308 a single time per round trip (in the laser cavity), and the laser output method is a fixed coupler. For the laser architecture 300 of prior art FIG. 3B, an optical signal may be configured to travel through each Vernier ring 307, 308 a single time per round trip, and the laser output method is a tunable Mach-Zehnder interferometer (MZI).

For the laser architecture 300 of prior art FIG. 3C, an optical signal may be configured to travel through each Vernier ring 307, 308 a single time per round trip, and the laser output method is ring thru-ports (“through ports”). As is understood, the laser architecture 300 of FIG. 3C is configured to have its laser output through two ring thru-ports. Furthermore, the laser architecture 300 of FIG. 3C combines the two ring thru-ports using an MZI, which needs a control circuit to tune the phase for maximum output, thus increasing device complexity and cost. Additionally, the laser architecture 300 of FIG. 3C uses a symmetrical optical splitter, with same/similar splitting ratio (˜50%) to the corresponding two branches and uses two asymmetrical Vernier rings for the disclosed Vernier ring 307, 308. In an alternative embodiment, the laser architecture 300 of FIG. 3C may instead use two symmetrical Vernier rings.

For the laser architecture 300 of prior art FIG. 3D, an optical signal may be configured to travel through each Vernier ring 307, 308 two times per round trip, and the laser output method is a tunable MZI. For the laser architecture 300 of prior art FIG. 3E, an optical signal may be configured to travel through each Vernier ring 307, 308 two times per round trip, and the laser output method is a fixed coupler. For the laser architecture 300 of FIG. 3F, an optical signal may be configured to travel through each Vernier ring 307, 308 two times per round trip, and the laser output method is a ring thru-port. In general, asymmetrical rings are used only when laser power needs to be taken out via ring thru-ports, such as the two Vernier rings 307, 308 in FIG. 3C, and the first Vernier ring 307 in FIG. 3F. In other cases, symmetrical Vernier rings are usually preferred.

For the disclosed laser architecture configurations of FIGS. 3A-3F, the ring waveguides on the corresponding Si photonics chips 305 can be either Si or SiN, depending on the application. Furthermore, for the above configurations of FIGS. 3A-3F, it should be noted that the laser output at the III-V gain chip 301 back facet is not suitable for integration and thus has not been considered.

It should be noted that each embodiment of FIG. 3A-3F may have certain shortcomings that limit their capabilities. The utilization of a fixed coupler or tunable MZI laser output methods results in higher optical loss and non-linearity effects, when compared to ring thru-port output methods. Furthermore, the implementation of an MZI introduces new requirements, such as the need for a corresponding control circuit, which increases cost and complexity. Additionally, as described above, laser architecture configurations configured to have the laser travel through each Vernier ring twice on a round trip may also be undesirable, as the associated optical losses from traveling through the Vernier rings is doubled compared to configurations that only pass through each Vernier ring once on a round trip.

Therefore, there is a need to solve the problems described above by providing a tunable laser architecture configured to tune lasers using symmetrical and asymmetrical Vernier rings while minimizing optical losses, non-linearity effect and other detrimental effects.

The aspects or the problems and the associated solutions presented in this section could be or could have been pursued; they are not necessarily approaches that have been previously conceived or pursued. Therefore, unless otherwise indicated, it should not be assumed that any of the approaches presented in this section qualify as prior art merely by virtue of their presence in this section of the application.

### BRIEF INVENTION SUMMARY

This Summary is provided to introduce a selection of concepts in a simplified form that are further described below in the Detailed Description. This Summary is not intended to identify key aspects or essential aspects of the claimed subject matter. Moreover, this Summary is not intended for use as an aid in determining the scope of the claimed subject matter.

In an aspect, a tunable laser architecture is provided, the tunable laser architecture comprising: a semiconductor gain chip having a first end and a second end, wherein a high reflectivity coating is disposed on the first end of the semiconductor gain chip; a photonics chip configured to be in optical communication with the semiconductor gain chip, such that the second end of the semiconductor gain chip is associated with a first end of the photonics chip, the photonics chip comprising: a laser input in optical communication with the semiconductor gain chip; a main waveguide in optical communication with the laser input; an optical splitter in optical communication with the main waveguide; a first branching waveguide in optical communication with the optical splitter, wherein the first branching waveguide is configured to be in optical communication with a laser output; a second branching waveguide in optical communication with the optical splitter; a first Vernier ring in optical communication with the first branching waveguide; a second Vernier ring in optical communication with the second branching waveguide; and a monitor pathway waveguide in optical communication with the first Vernier ring and the second Vernier ring, wherein the monitor pathway waveguide is configured to be in optical communication with a monitor photodetector; wherein the optical splitter is configured to split power of an incoming laser from the main waveguide between the first branching waveguide and the second branching waveguide and the first Vernier ring and second Vernier ring have different free spectral ranges. Thus, an advantage is that a tunable laser architecture that utilizes Vernier rings may experience lesser optical losses than other alternative tunable laser architectures known in the industry. Another advantage is that the small size of Vernier rings helps to keep the corresponding tunable laser architecture small, to minimize material costs and be utilized in applications with limited available space. Another advantage is that a laser may only pass through each Vernier ring a singular time on round trip from the semiconductor gain chip through the photonics chip and back to the semiconductor gain chip, thus further minimizing optical losses. Another advantage is the disclosed tunable laser architecture does not require a control circuit to tune the phase for maximum output), which leads to less power consumption and higher yield. Another advantage is that using an asymmetrical Vernier ring with a laser output thru-port has the advantage of reduced power density in the corresponding asymmetrical Vernier ring, leading to reduced nonlinearity effect. Furthermore, the optical splitter may be asymmetrical to facilitate an asymmetrical distribution of optical power between the first and second Vernier rings, thus allowing for further optimized device function.

In another aspect, a tunable laser architecture is provided, the tunable laser architecture comprising: a semiconductor gain chip; a photonics chip in optical communication with the semiconductor gain chip, the photonics chip having: an optical splitter in optical communication with the semiconductor gain chip; a first branching waveguide in optical communication with the optical splitter, wherein the first branching waveguide is configured to be in optical communication with a laser output; a second branching waveguide in optical communication with the optical splitter; a first Vernier ring in optical communication with the first branching waveguide; a second Vernier ring in optical communication with the second branching waveguide; and a monitor pathway waveguide in optical communication with the first Vernier ring and the second Vernier ring. Again, an advantage is that a tunable laser architecture that utilizes Vernier rings may experience lesser optical losses than other alternative tunable laser architectures known in the industry. Another advantage is that the small size of Vernier rings helps to keep the corresponding tunable laser architecture small, to minimize material costs and be utilized in applications with limited available space. Another advantage is that a laser may only pass through each Vernier ring a singular time on round trip from the semiconductor gain chip through the photonics chip and back to the semiconductor gain chip, thus further minimizing optical losses. Another advantage is the disclosed tunable laser architecture does not require a control circuit to tune the phase for maximum output), which leads to less power consumption and higher yield. Another advantage is that using an asymmetrical Vernier ring with a laser output thru-port has the advantage of reduced power density in the corresponding asymmetrical Vernier ring, leading to reduced nonlinearity effect. Furthermore, the optical splitter may be asymmetrical to facilitate an asymmetrical distribution of optical power between the first and second Vernier rings, thus allowing for further optimized device function.

In another aspect, a tunable laser architecture is provided, the tunable laser architecture comprising: an asymmetric optical splitter; a first branching waveguide in optical communication with the asymmetrical optical splitter, wherein the first branching waveguide is configured to be in optical communication with a laser output; a second branching waveguide in optical communication with the asymmetrical optical splitter; a first asymmetrical Vernier ring in optical communication with the first branching waveguide; and a second symmetrical Vernier ring in optical communication with the second branching waveguide. Again, an advantage is that a tunable laser architecture that utilizes Vernier rings may experience lesser optical losses than other alternative tunable laser architectures known in the industry. Another advantage is that the small size of Vernier rings helps to keep the corresponding tunable laser architecture small, to minimize material costs and be utilized in applications with limited available space. Another advantage is that a laser may only pass through each Vernier ring a singular time on round trip from the semiconductor gain chip through the photonics chip and back to the semiconductor gain chip, thus further minimizing optical losses. Another advantage is the disclosed tunable laser architecture does not require a control circuit to tune the phase for maximum output), which leads to less power consumption and higher yield. Another advantage is that using an asymmetrical Vernier ring with a laser output thru-port has the advantage of reduced power density in the corresponding asymmetrical Vernier ring, leading to reduced nonlinearity effect. Furthermore, the optical splitter is asymmetrical to facilitate an asymmetrical distribution of optical power between the first and second Vernier rings, thus allowing for further optimized device function.

The above aspects or examples and advantages, as well as other aspects or examples and advantages, will become apparent from the ensuing description and accompanying drawings.

### BRIEF DESCRIPTION OF THE DRAWINGS

For exemplification purposes, and not for limitation purposes, aspects, embodiments or examples of the invention are illustrated in the figures of the accompanying drawings, in which:

FIG. 1 illustrates an example of a tunable laser architecture having Vernier rings, according to an aspect.

FIG. 2 illustrates a typical transmission spectrum for Vernier rings of a laser architecture using the Vernier rings for wavelength control, according to an aspect.

FIGS. 3A-3E illustrate prior art laser architectures having Vernier rings, according to an aspect.

FIG. 3F illustrates a laser architecture having two Vernier rings and a ring thru-port laser output method, according to an aspect.

FIG. 3G illustrates a table describing the configurations of the laser architectures of FIG. 3A-3F, according to an aspect.

FIG. 4 illustrates a tunable laser architecture having a first asymmetrical Vernier ring and a second symmetrical Vernier ring, according to an aspect.

FIG. 5 illustrates a performance chart for optical devices, according to an aspect.

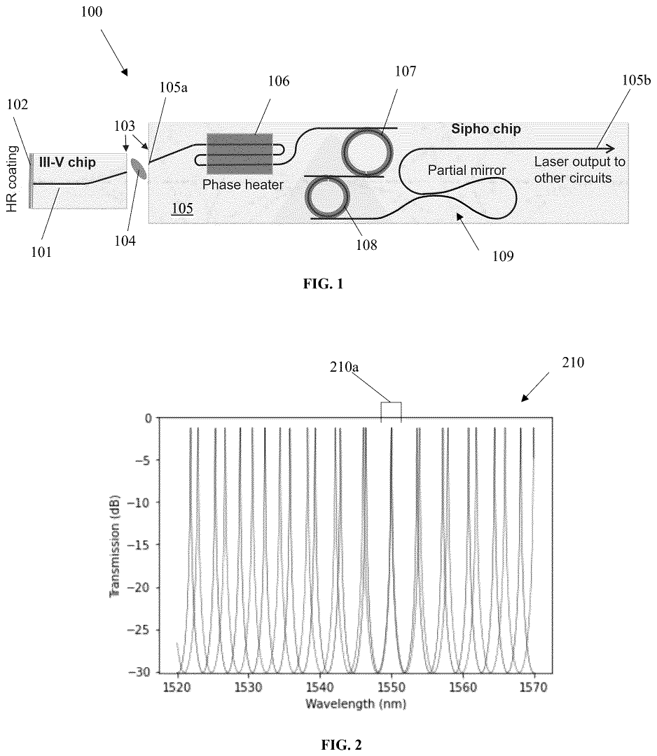

### DETAILED DESCRIPTION

What follows is a description of various aspects, embodiments and/or examples in which the invention may be practiced. Reference will be made to the attached drawings, and the information included in the drawings is part of this detailed description. The aspects, embodiments and/or examples described herein are presented for exemplification purposes, and not for limitation purposes. It should be understood that structural and/or logical modifications could be made by someone of ordinary skills in the art without departing from the scope of the invention. Therefore, the scope of the invention is defined by the accompanying claims and their equivalents.

It should be understood that, for clarity of the drawings and of the specification, some or all details about some structural components or steps that are known in the art are not shown or described if they are not necessary for the invention to be understood by one of ordinary skills in the art.

For the following description, it can be assumed that most correspondingly labeled elements across the figures (e.g., 101 and 301, etc.) possess the same characteristics and are subject to the same structure and function. If there is a difference between correspondingly labeled elements that is not pointed out, and this difference results in a non-corresponding structure or function of an element for a particular embodiment, example or aspect, then the conflicting description given for that particular embodiment, example or aspect shall govern.

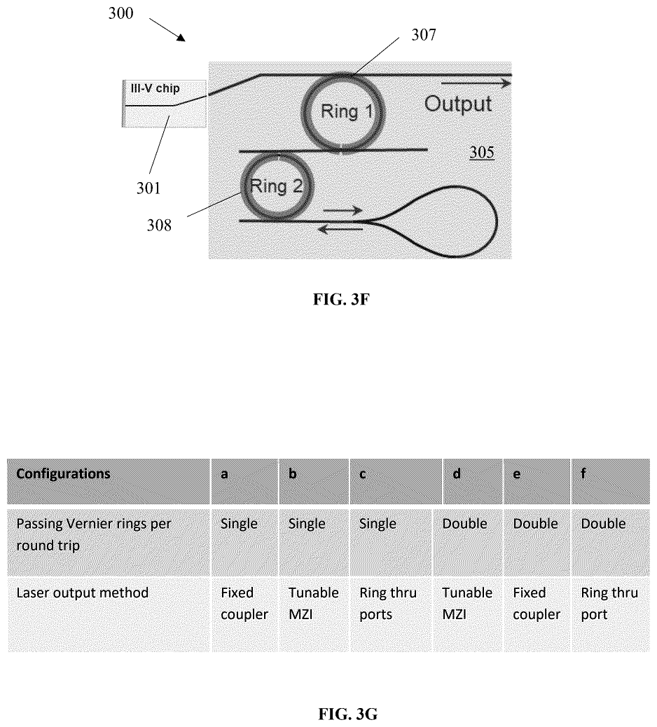

FIG. 4 illustrates a tunable laser architecture 411 having a first asymmetrical Vernier ring 417 and a second symmetrical Vernier ring 418, according to an aspect. In an embodiment, the disclosed tunable laser architecture 411 having asymmetrical (asymmetric) and symmetrical (symmetric) Vernier rings 417, 418 may comprise a III-V gain chip 401 having a high reflectivity coating 402 on a first end 401a of the III-V gain chip 401 and an anti-reflection coating 403 on a second end 401b of the III-V gain chip 401, to ensure lasers are not reflected off of the second end of the III-V chip. The tunable laser architecture 411 may further comprise a photonics chip 412 optically coupled with the second end 401b of the III-V gain chip 401. As such, the tunable laser architecture 411 may be configured such that a laser may travel between the III-V gain chip 401 and the photonics chip 412.

In an embodiment, the photonics chip 412 may comprise a laser input 412a disposed on a first end 412c of the photonics chip 412, wherein the laser input 412a is configured to be optically coupled with the III-V gain chip 401, a main waveguide 413 optically connected with the laser input 412a, an optical splitter 414 optically connected with the main waveguide 413, a first branching waveguide 415 optically connected with the optical splitter 414, and a second branching waveguide 416 optically connected to the optical splitter 414, such that light traveling through the main waveguide 413 toward the optical splitter 414 is split between the first and second branching waveguides 415, 416 based on a corresponding splitting ratio of the optical splitter 414. The first branching waveguide 415 may be optically connected with the laser output 412b of the tunable laser architecture 411. The photonics chip 412 may further comprise a first Vernier ring 417 optically coupled with the first branching waveguide 415, a second Vernier ring 418 optically coupled with the second branching waveguide 416 and a monitor pathway waveguide 419 optically coupled with the first Vernier ring 417 and the second Vernier ring 418, as seen in FIG. 4. In an embodiment, this monitor pathway waveguide 419 may be optically connected with a monitor device/monitoring photodetector (“MPD”) 424, as indicated by the dotted line 425 between the monitor pathway waveguide 419 and the monitoring photodetector 424.

In an embodiment, the photonics chip 412 may have an anti-reflection coating 403, wherein said anti-reflection coating 403 is disposed at least on the first end 412c of the photonics chip 412. As seen in FIG. 4, the anti-reflection coating 403 disposed on the first end 412c of the photonics chip 412 may be facing, engaged with or otherwise associated with the anti-reflection coating 403 disposed on the second end 401b of the III-V gain chip 401, as a result of the first end 412c of the photonics chip 412 being configured to be associated with the second end 401b of the III-V gain chip 401, to facilitate optical communication between photonics chip 412 and the III-V gain chip 401. This utilization of the anti-reflection coatings 403 applied to corresponding associated portions of the semiconductor gain chip 401 and the photonics chip 412 is configured to minimize optical reflections and optical power loss for light traveling between the semiconductor gain chip 401 and the photonics chip 412. For clarity, the anti-reflection coating 403 on the semiconductor gain chip 401 may be referred to as a “first anti-reflection coating” and the anti-reflection coating 403 on the photonics chip 412 may be referred to as a “second anti-reflection coating.”

As articulated hereinabove, the associations of the above elements may also be described more broadly in terms of being in “optical communication” with each other. For example, it may be stated that the photonics chip 412 is configured to be in optical communication with the semiconductor gain chip 401. For the embodiment of FIG. 4 it, may be stated that the laser input 412a is configured to be in optical communication with the semiconductor gain chip 401, the main waveguide 413 may be in optical communication with the laser input 412a, the optical splitter 414 may be in optical communication with the main waveguide 413, the first branching waveguide 415 may be in optical communication with the optical splitter 414, and the second branching waveguide 416 may be in optical communication the optical splitter 414. Furthermore, for the photonics chip 412 of FIG. 4, it may be stated that the first branching waveguide 415 may be in optical communication with the laser output 412b, the first Vernier ring 417 may be in optical communication with the first branching waveguide 415, the second Vernier ring 418 may be in optical communication with the second branching waveguide 416, the monitor pathway waveguide 419 may be in optical communication with the first Vernier ring 417, the second Vernier ring 418, and the monitoring photodetector 424.

In an embodiment, the disclosed optical splitter 414 may be asymmetrical in both shape and splitting ratio, such that the first branching waveguide 415 and the second branching waveguide 416 that are optically branched from the optical splitter 414 each receive a different amount of optical power from a laser traveling through the main waveguide 413 toward the optical splitter 414, based upon the optical splitter's corresponding splitting ratio. In said embodiment, the splitting ratio of this asymmetric optical splitter 414 may be 75%/25%, wherein 75% of the optical power routed to/received by the optical splitter 414 from the main waveguide 413 is directed to the first branching waveguide 415 and the first Vernier ring 417. As such, the remaining 25% of the optical power routed to/received by the optical splitter 414 from the main waveguide 413 may be directed to the second branching waveguide 416 and the second Vernier ring 418. While the splitting ratio described for the embodiment of FIG. 4 may be 75%/25%, as described above, it should be understood that, in alternative embodiments, the splitting ratio may be adjusted based on the performance and application needs of the corresponding device.

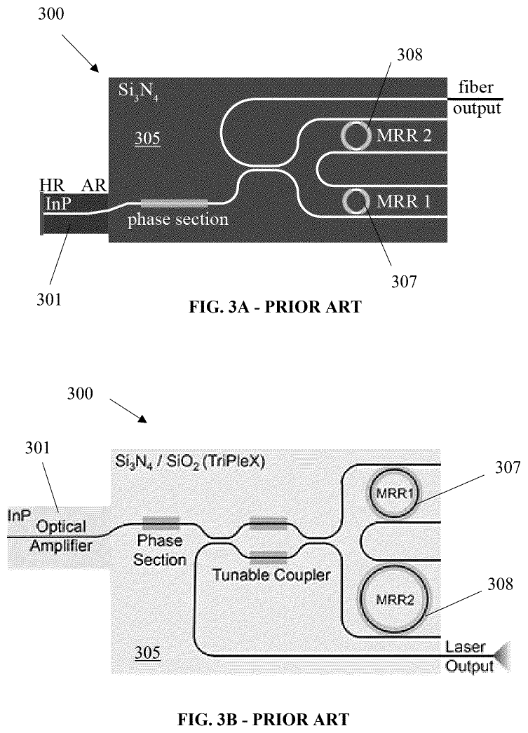

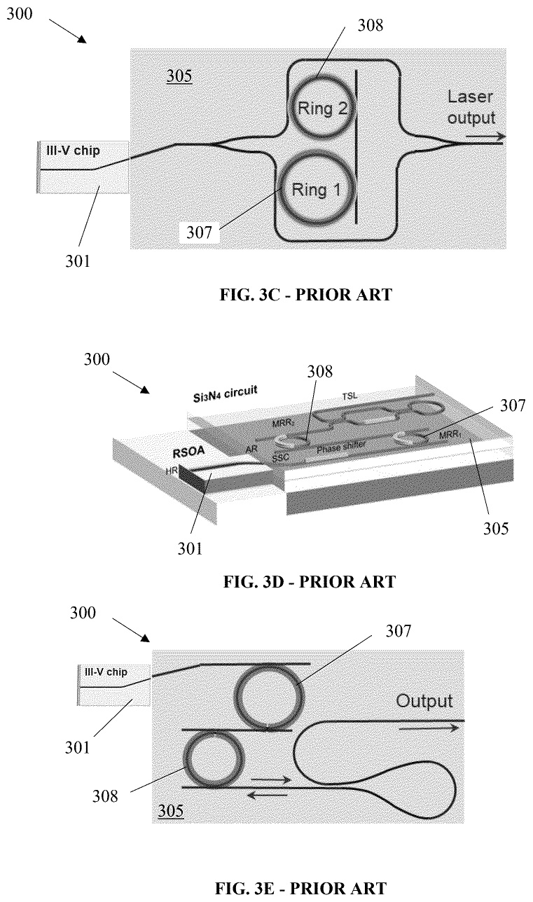

As can be seen in FIG. 4, the first and second Vernier rings 417, 418 may not be identical to each other. In an embodiment, the first Vernier ring 417 may have a greater diameter than the second Vernier ring 418. As disclosed hereinabove, this difference in the sizes of the first and second Vernier rings 417, 418 may be configured to facilitate the alignment of resonance pairs between the Vernier rings at a desired emission wavelength, as discussed hereinabove in FIG. 2. In another embodiment, the first Vernier ring 417 may have a lesser diameter than the second Verner ring 418. In yet another embodiment, the first Vernier ring 417 and the second Vernier ring 418 may be the same size but have different waveguide widths or materials. It should be understood that other suitable alternative embodiments may be implemented as well, as long as said embodiments also facilitate the two Vernier rings 417, 418 having different FSRs, and thus aligned resonance pairs at a desired emission wavelength. Furthermore, the disclosed tunable laser architecture 411 is configured for laser output via a single ring thru-port. In other words, the laser output 412b may be disposed off of a singular one of the Vernier rings, which in the case of the tunable laser architecture 411 of FIG. 4, is the first Vernier ring 417. With the disclosed configuration of the photonics chip 412 of FIG. 4, the power traveling through the photonics chip 412 goes in and out of the first and second Vernier rings 417, 418 through the asymmetric optical splitter 414. As is understood, the asymmetry of an asymmetrical Vernier Ring allows for a significant laser output at one of the ring thru-ports, as a result of the difference of the coupling coefficients (e.g., greater laser output occurs at the thru-port whose coupling coefficient is smaller than the other), leading to more power being sent through one of the thru-ports of said asymmetrical Vernier Ring.

In an embodiment, the first Vernier ring 417 may have an asymmetric coupling with its two bus waveguides. As is understood by the asymmetric coupling of the first Vernier ring 417 with its two bus waveguides (e.g., the first branching waveguide 415 and the monitor pathway waveguide 419), the coupling coefficients of first Vernier ring 417 with its two bus waveguides are different. In the disclosed embodiment of FIG. 4, the coupling coefficient of the first Vernier ring 417 with the first branching waveguide 415 is much smaller than the coupling coefficient of the first Vernier ring 417 with the monitor pathway waveguide 419 (e.g., the coupling coefficient of the first Vernier ring 417 with the first branching waveguide 415 is no more than half the coupling coefficient of the first Vernier ring 417 with the monitor pathway waveguide 419). In other words, in the disclosed embodiment of FIG. 4, the first Vernier ring 417 may be described as an “asymmetrical Vernier ring” and thus referred to as the first asymmetrical Vernier ring 417. In contrast, the second Vernier ring 418 may be symmetrical in its coupling with its two corresponding bus waveguides. In other words, in the disclosed embodiment of FIG. 4, the coupling coefficient of the second Vernier ring 418 with the second branching waveguide 416 is the same as (or sufficiently close to, e.g., within 10% difference) the coupling coefficient of the second Vernier ring 418 with the monitor pathway waveguide 419. As such, in the disclosed embodiment of FIG. 4, the second Vernier ring 418 may be described as a “symmetrical Vernier ring” and thus referred to as the second symmetrical Vernier ring 418.

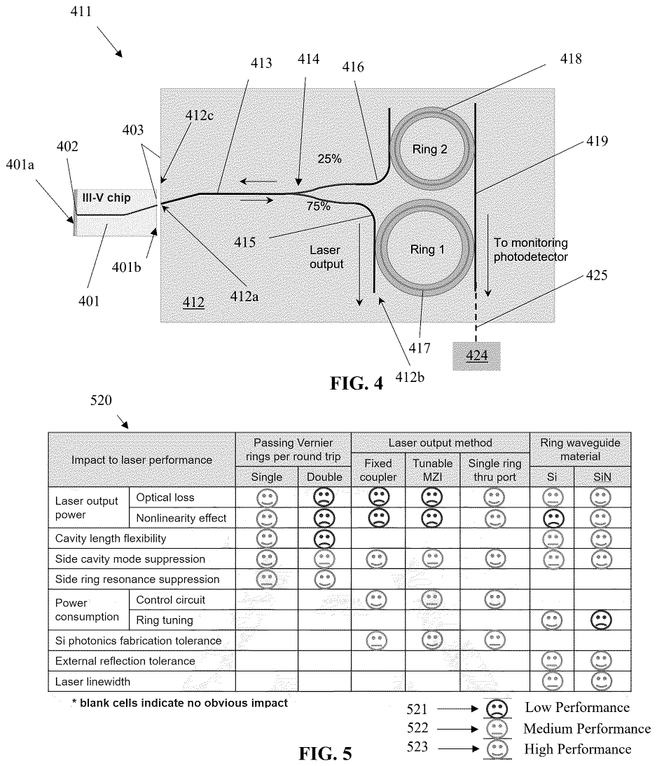

The described configuration of the disclosed tunable laser architecture 411 having the asymmetrical and symmetrical Vernier rings 417, 418 of FIG. 4 may provide certain benefits. One such benefit is that each round trip passage through the disclosed tunable laser architecture 411 (e.g., from the semiconductor gain chip 401 through the photonics chip 412 and back to the semiconductor gain chip 401) only has a single pass through each Vernier ring 417, 418. This passage of a laser through each Vernier ring 417, 418 only a single time on a round trip positively impacts laser architecture performance by minimizing optical losses and non-linearity effects. Furthermore, this single passage of the laser through each Vernier ring 417, 418 may also positively influence cavity length flexibility and side cavity mode suppression, as emphasized in the optical performance chart of FIG. 5.

Additionally, the disclosed tunable laser architecture 411 may be configured for laser output via a single-ring thru-port, without going through ring losses. This feature may also provide low optical loss and low non-linearity effects within simple optical circuits and simple control circuits utilizing the disclosed tunable laser architecture 411. Furthermore, using a single-ring thru-port for laser output without going through ring losses may also have the benefit of positively impacting side cavity mode suppression. In addition, it should be understood that the disclosed Si photonics chip 412 of the tunable laser architecture 411 of FIG. 4 may be configured to utilize either Si Vernier rings or SiN Vernier rings for the first and second Vernier rings 417, 418 (e.g. both or either of Vernier rings 417, 418 may be made of silicon or silicon nitride). As such, the inherent benefits/capabilities of either material may be provided to the tunable laser architecture 411, as desired within a specific application.

As is understood, the disclosed tunable laser architecture 411 of FIG. 4 does not require a control circuit to tune the phase for maximum output, which leads to less power consumption and higher yield. Additionally, using an asymmetrical Vernier ring 417 with a laser output thru-port has the advantage of reduced power density in the corresponding asymmetrical Vernier ring 417, leading to reduced nonlinearity effect.

The benefits/capabilities enabled by the particular configuration of the disclosed tunable laser architecture 411 having asymmetrical and symmetrical Vernier rings 417, 418 will be described in greater detail hereinbelow.

FIG. 5 illustrates a performance chart 520 for optical devices, according to an aspect. As described hereinabove, the disclosed tunable laser architecture 411 of FIG. 4 may be characterized by its single pass through each Vernier ring on a round trip, laser output through a single ring thru-port, and compatibility with either Si or SiN Vernier ring waveguide materials. As is readily understood upon observation of the disclosed performance chart 520, these characteristics may be advantageous for a plurality of reasons. It should be understood that a smile symbol 523 indicates high performance, a neutral symbol 522 indicates fair/moderate performance and the frown symbol 521 indicates poor/low performance in FIG. 5.

As expressed in the performance chart 520 of FIG. 5, having an optical/laser architecture characterized by having a laser only pass through each Vernier ring once on a round trip through the tunable laser architecture may be preferred in many applications. As articulated in FIG. 5, a laser architecture characterized by having a laser only pass through each Vernier ring once on a round trip may have the advantages of having reduced optical losses, reduced non-linearity effects, improved cavity length flexibility and improved side cavity mode suppression, when compared to laser architectures having a laser that passes through each Vernier ring twice on a round trip. It should be noted that laser infrastructures configured for a single pass of each ring per round trip may also exhibit acceptable/fair side ring resonance suppression.

Additionally, a laser architecture having the single ring thru-port for laser output may also exhibit several advantages over laser architectures having other laser output methods. In an embodiment, a laser architecture having a single ring thru-port for laser output may have the advantages of having reduced optical losses, reduced non-linearity effects, improved side cavity mode suppression and reduced power consumption for control circuits. It should also be noted that this laser output method may also have acceptable/fair Si photonics fabrication tolerance.

Furthermore, as described hereinabove, the disclosed tunable laser architecture 411 of FIG. 4 having asymmetrical and symmetrical Vernier rings 417, 418 may be configured in such a manner as to enable the utilization of either Si or SiN Vernier rings. As is understood, selective utilization of Si Vernier rings or SiN Vernier rings may facilitate the advantages inherent with said materials, such as the reduced optical losses associated with the usage of SiN Vernier ring waveguides or improved power consumption while ring tuning using Si Vernier ring waveguides. As is understood, a suitable material for the Vernier rings may be selected and utilized accordingly based upon the needs of the corresponding tunable laser architecture. It should be noted that cells of the shown performance chart 520 that do not include a corresponding symbol should be understood as indicating a particular choice/selection in a category does not have an obvious impact on performance (e.g., having a tunable laser architecture with a single ring thru-port for its laser output may not noticeably impact its cavity length flexibility.)

As is understood, the disclosed tunable laser architecture 411 of FIG. 4 having asymmetrical and symmetrical Vernier rings may be configured to provide the various benefits disclosed herein. Again, while the disclosed tunable laser architecture 411 of FIG. 4 may be capable of utilizing either Si or SiN Vernier rings, it should be understood that the material utilized for the tunable laser architecture may be selected based on which material is more advantageous for the selected application. Furthermore, the disclosed tunable laser architecture configuration 411 of FIG. 4 may experience low optical losses and reduced power consumption in optical and control circuits, while allowing a simpler tuning structure that minimizes potential points of failure.

It may be advantageous to set forth definitions of certain words and phrases used in this patent document. The term “couple” and its derivatives refer to any direct or indirect communication between two or more elements, whether or not those elements are in physical contact with one another. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

Further, as used in this application, “plurality” means two or more. A “set” of items may include one or more of such items. Whether in the written description or the claims, the terms “comprising,” “including,” “carrying,” “having,” “containing,” “involving,” and the like are to be understood to be open-ended, i.e., to mean including but not limited to. Only the transitional phrases “consisting of” and “consisting essentially of,” respectively, are closed or semi-closed transitional phrases with respect to claims.

If present, use of ordinal terms such as “first,” “second,” “third,” etc., in the claims to modify a claim element does not by itself connote any priority, precedence or order of one claim element over another or the temporal order in which acts of a method are performed. These terms are used merely as labels to distinguish one claim element having a certain name from another element having a same name (but for use of the ordinal term) to distinguish the claim elements. As used in this application, “and/or” means that the listed items are alternatives, but the alternatives also include any combination of the listed items.

Throughout this description, the aspects, embodiments or examples shown should be considered as exemplars, rather than limitations on the apparatus or procedures disclosed or claimed. Although some of the examples may involve specific combinations of method acts or system elements, it should be understood that those acts and those elements may be combined in other ways to accomplish the same objectives.

Acts, elements and features discussed only in connection with one aspect, embodiment or example are not intended to be excluded from a similar role(s) in other aspects, embodiments or examples.

Aspects, embodiments or examples of the invention may be described as processes, which are usually depicted using a flowchart, a flow diagram, a structure diagram, or a block diagram. Although a flowchart may depict the operations as a sequential process, many of the operations can be performed in parallel or concurrently. In addition, the order of the operations may be re-arranged. With regard to flowcharts, it should be understood that additional and fewer steps may be taken, and the steps as shown may be combined or further refined to achieve the described methods.

If means-plus-function limitations are recited in the claims, the means are not intended to be limited to the means disclosed in this application for performing the recited function, but are intended to cover in scope any equivalent means, known now or later developed, for performing the recited function.

Claim limitations should be construed as means-plus-function limitations only if the claim recites the term “means” in association with a recited function.

If any presented, the claims directed to a method and/or process should not be limited to the performance of their steps in the order written, and one skilled in the art can readily appreciate that the sequences may be varied and still remain within the spirit and scope of the present invention.

Although aspects, embodiments and/or examples have been illustrated and described herein, someone of ordinary skills in the art will easily detect alternate of the same and/or equivalent variations, which may be capable of achieving the same results, and which may be substituted for the aspects, embodiments and/or examples illustrated and described herein, without departing from the scope of the invention. Therefore, the scope of this application is intended to cover such alternate aspects, embodiments and/or examples. Hence, the scope of the invention is defined by the accompanying claims and their equivalents. Further, each and every claim is incorporated as further disclosure into the specification.

What is claimed is:

1. A tunable laser architecture comprising:
a semiconductor gain chip having a first end and a second end, wherein a high reflectivity coating is disposed on the first end of the semiconductor gain chip;
a photonics chip configured to be in optical communication with the semiconductor gain chip, such that the second end of the semiconductor gain chip is associated with a first end of the photonics chip, the photonics chip comprising:
a laser input in optical communication with the semiconductor gain chip;
a main waveguide in optical communication with the laser input;
an optical splitter in optical communication with the main waveguide;
a first branching waveguide in optical communication with the optical splitter, wherein the first branching waveguide is configured to be in optical communication with a laser output;
a second branching waveguide in optical communication with the optical splitter;
a first Vernier ring in optical communication with the first branching waveguide;
a second Vernier ring in optical communication with the second branching waveguide; and
a monitor pathway waveguide in optical communication with the first Vernier ring and the second Vernier ring, wherein the monitor pathway waveguide is configured to be in optical communication with a monitor photodetector;
wherein the optical splitter is configured to split power of an incoming laser from the main waveguide between the first branching waveguide and the second branching waveguide and the first Vernier ring and second Vernier ring have different free spectral ranges.

2. The tunable laser architecture of claim 1, wherein the optical splitter is configured to route 75% of optical power of the incoming laser from the main waveguide through the first branching waveguide and 25% of the optical power of the incoming laser from the main waveguide through the second branching waveguide.

3. The tunable laser architecture of claim 1, wherein a laser traveling from the main waveguide to the semiconductor gain chip is configured to reflect off of the high reflectivity coating and return to the main waveguide.

4. The tunable laser architecture of claim 1, wherein the photonics chip is configured such that a laser traveling from the semiconductor gain chip through the photonics chip and back to the semiconductor gain chip is configured to only travel through the first Vernier ring and the second Vernier ring a single time.

5. The tunable laser architecture of claim 1, wherein the tunable laser architecture is configured for laser output via a single ring thru-port of the first Vernier ring.

6. The tunable laser architecture of claim 1, wherein the first Vernier ring has a greater diameter than the second Vernier ring.

7. The tunable laser architecture of claim 1, further comprising a first anti-reflection coating on the second end of the semiconductor gain chip and a second anti-reflection coating on the first end of the photonics chip.

8. The tunable laser architecture of claim 1, wherein the first Vernier ring is asymmetrical and the second Vernier ring is symmetrical.

9. A tunable laser architecture comprising:
a semiconductor gain chip;
a photonics chip in optical communication with the semiconductor gain chip, the photonics chip having:
an optical splitter in optical communication with the semiconductor gain chip;
a first branching waveguide in optical communication with the optical splitter, wherein the first branching waveguide is configured to be in optical communication with a laser output;
a second branching waveguide in optical communication with the optical splitter;
a first Vernier ring in optical communication with the first branching waveguide;
a second Vernier ring in optical communication with the second branching waveguide; and
a monitor pathway waveguide in optical communication with the first Vernier ring and the second Vernier ring.

10. The tunable laser architecture of claim 9, wherein the optical splitter is configured to route 75% of optical power of an incoming laser from the main waveguide through the first branching waveguide and 25% of the optical power of the incoming laser from the main waveguide through the second branching waveguide.

11. The tunable laser architecture of claim 9, wherein the photonics chip is configured such that a laser traveling from the optical splitter, through the photonics chip, and back to the optical splitter is configured to only travel through the first Vernier ring and the second Vernier ring a single time.

12. The tunable laser architecture of claim 9, wherein the tunable laser architecture is configured for laser output via a single ring thru-port of the first Vernier ring.

13. The tunable laser architecture of claim 9, wherein the first Vernier ring has a different diameter than the second Vernier ring.

14. The tunable laser architecture of claim 9, wherein the first Vernier ring and the second Vernier ring are made from different materials.

15. The tunable laser architecture of claim 9, wherein the first Vernier ring is asymmetrical, and the second Vernier ring is symmetrical.

16. A tunable laser architecture comprising:
an asymmetric optical splitter;
a first branching waveguide in optical communication with the asymmetrical optical splitter, wherein the first branching waveguide is configured to be in optical communication with a laser output;
a second branching waveguide in optical communication with the asymmetrical optical splitter;
a first asymmetrical Vernier ring in optical communication with the first branching waveguide; and
a second symmetrical Vernier ring in optical communication with the second branching waveguide.

17. The tunable laser architecture of claim 16, wherein the asymmetrical optical splitter is configured to route 75% of optical power from an incoming laser from the main waveguide through the first branching waveguide and 25% of optical power from the incoming laser from the main waveguide through the second branching waveguide.

18. The tunable laser architecture of claim 16, wherein the photonics chip is configured such that a laser traveling from the asymmetrical optical splitter, through the photonics chip, and back to the asymmetrical optical splitter is configured to only travel through the first asymmetrical Vernier ring and the second symmetrical Vernier ring a single time.

19. The tunable laser architecture of claim 16, wherein the tunable laser architecture is configured for laser output via a single ring thru-port of the first asymmetrical Vernier ring.

20. The tunable laser architecture of claim 16, wherein the first asymmetrical Vernier ring has a different diameter than the second symmetrical Vernier ring.
